(19) United States
(12) Patent Application Publication
(10) Pub. No.: US 2021/0288474 A1
(43) Pub. Date: Sep. 16, 2021

(54) SWITCHING DEVICE ARRANGEMENT

(71) Applicant: Oliver FENKER, Warthausen (DE)

(72) Inventor: Oliver FENKER, Warthausen (DE)

(21) Appl. No.: 17/334,377

(22) Filed: May 28, 2021

Related U.S. Application Data
(63) Continuation of application No. PCT/EP2019/080817, filed on Nov. 11, 2019.

(30) Foreign Application Priority Data
Nov. 29, 2018 (DE) 10 2018 130 342.4

(51) Int. Cl. H02B 1/20; H02B 1/21; H02B 1/30

(52) U.S. Cl. CPC H02B 1/205; H02B 1/30; H02B 1/21

(57) ABSTRACT

The present invention relates to a switching device arrangement, comprising a plurality of switching devices, which are mounted in common on a mounting profiled rail, in particular a top hat rail, wherein the switching devices are connected to a bus system comprising at least one data bus and/or energy bus for transferring control signals and/or for supplying energy, wherein the bus system is integrated at least partially into the mounting profiled rail and the switching devices have bus connections for connecting to the bus system in the mounting profiled rail.

### CROSS-REFERENCE TO RELATED APPLICATIONS

This application is a continuation of International Patent Application Number PCT/EP2019/080817 filed Nov. 11, 2019, which claims priority to German Patent Application Number DE 10 2018 130 342.4 filed Nov. 29, 2018, the contents of which are incorporated herein by reference in their entireties.

### BACKGROUND

The present invention relates to a switching device arrangement comprising a plurality of switching devices that are mounted together on a mounting profile rail, in particular a top hat rail, wherein the switching devices are connected to a bus system comprising at least one databus and/or energy bus for transmitting control signals and/or for energy supply.

Switchgear cabinets for large technical systems such as wind turbines or for transfer systems or hoisting systems such as cranes, construction cranes, harbor cranes or offshore cranes as a rule comprise a plurality of switching devices that can be mounted on a common top hat rail by being pushed on or latched on and that can carry out different switching functions. Such switching devices can be used, for example, to switch and/or protect the switching circuits of the main circuit. Alternative or additional switching devices can be used to form the logic of the control circuit. It is equally possible that a switching device for the main circuit has additional contacts for the connection in the circuit.

Power electronic components via which said systems or transfer units that are connected to the switchgear cabinet can be supplied with electrical power and controlled can also be accommodated in the previously named switchgear cabinets.

The mounting of said switching devices is conventionally relatively laborious despite the pushing or latching onto the top hat rail being simple per se since the switching devices still have to be wired with one another. A hardwiring of the logic or of a portion of the logic is typically implemented with the aid of the control circuit, with an additional logic also being able to be present in the form of a programmable control. Said hardwired logic of the control circuit is, however, not only very laborious and prone to error, in particular due to its many connection points, but is also less flexible so that it can only be subsequently changed with a great effort, for example on a reconfiguration or retrofitting of the system or crane. In addition there is the fact that the hardwired logic of the control circuit typically requires that additional switching elements have to be attached to individual switching devices for the main circuit and the control circuit. This is a larger problem for servicing since it has the consequence that switching devices are used in a very large number of different embodiments in the field.

To at least achieve a certain simplification, it has therefore already been proposed to use switching devices that are connectable to a bus system and that are connectable to a bus system via a bus connection device via which the switching devices can be controlled and/or parameterized. Document EP 1 258 957 B1, for example, shows a switching device system for facilities engineering in which the switching devices that can be pushed onto a top hat rail comprise respective plug-in contacts at the right and at the left to be connected to one another. The switching devices can here be addressed by a base module via a bus system. In addition to the plug-in contacts at the side surfaces that can be pushed onto one another, the switching devices comprise further plug-in connectors for connecting further wiring lines or energy supply lines.

Document DE 197 48 429 A1 similarly describes a bus enabled switching device that can be pushed onto a top hat rail. In a similar manner to the previously described EP 1 258 957 B1, the switching device comprises a plurality of plug-in contacts to be able to be connected to an energy bus, a databus, and an auxiliary energy bus. The switching device itself is here subdivided into a plurality of part modules at which the different plug-in contacts for the bus systems are implemented.

Even though said bus enabled switching devices already bring about a certain simplification in the mounting, a significant mounting effort still remains as well as a certain error susceptibility on the connection of the various plug-in contacts. The problem moreover remains that only mutually compatible switching devices from the same manufacturer or of the same type can be used since an arrangement of an older switching device that is not bus enabled interrupts the signal chain between the switching devices.

### SUMMARY

Starting from this, it is the underlying object of the present invention to provide an improved switching device arrangement and an improved switchgear cabinet having such a switching device arrangement that avoid disadvantages of the prior art and further develop the latter in an advantageous manner. A further simplified mounting and reconfigurability of the switching device arrangement should in particular be achieved, with the system also remaining compatible with older switching devices or switching devices of different types.

In accordance with the invention, said object is achieved by a switching device arrangement in accordance with claim 1 and by a switchgear cabinet in accordance with claim 13. Preferred embodiments of the invention are the subject of the dependent claims.

It is therefore proposed to relocate at least a part of the bus system in the top hat rail and to connect the switching devices by contact with said bus system or to its part by the top hat rail. In accordance with the invention, the bus system is at least partially integrated in the mounting profile rail, in particular the top hat rail, with the switching device having bus connectors for connection to the bus system in the mounting profile rail. The mounting is hereby further simplified since the switching devices are automatically connected to the bus system on the placing or pushing onto the top hat rail.

The switching devices can still have conventional contacts for the main circuit while the connection to the control circuit takes place via the bus system so that the commands for the control of the switching device can be transmitted via the bus system.

Said mounting profile rail can comprise rail sections in a further development of the invention, in particular rail sections mutually insulated from one another, in which different bus system components can be accommodated. In a further development of the invention, at least the energy bus of the bus system via which an energy supply of the switching devices can take place can be integrated in the mounting profile rail.

A voltage supply line and a ground potential connector or GND connector can in particular be integrated in different rail sections electrically insulated from one another.

Alternatively or additionally to said energy bus, a databus can also be integrated in the mounting profile rail. If said energy bus is simultaneously integrated in the mounting profile rail, the databus and the energy bus can be accommodated in different rail sections electrically insulated from one another. Said voltage supply lines and ground connector lines can, for example, be accommodated in oppositely disposed fold sections or marginal sections of the rail, while the data supply bus can be accommodated in a central base section of the top hat rail that is lower lying, for example.

It would generally also be possible in dependence on the configuration of the bus system to combine the energy supply and the data transmission in a common bus strand.

Alternatively or additionally to a wired bus, in particular a databus, in the mounting profile rail, the bus system for the control and/or energy supply of the switching devices can, however, also comprise a wireless bus strand, in particular a radio bus, to transmit data and/or control signals between the switching devices and/or from the switching devices to a control module and/or vice versa, in particular by radio.

The switching devices can here be bus connectors in the form of wireless transmission and/or reception modules to receive data and/or control signals and/or to feed them into the bus system.

To be able to mount the switching devices in a simple manner at said mounting profile rail, it is advantageous for the switching devices each to have a mounting profile that is at least sectionally complementary to or compatible with the mounting profile rail and that can, for example, be provided at the lower side of the switching devices. Said mounting profile of the switching devices is configured to hold the respective switching device at the mounting profile rail with shape matching and/or to be pushable thereon and/or to be latchable thereto. The mounting profile of the switching device can, for example, have a hollow at the lower side of the switching devices having claw-like marginal webs, for example, that can engage around oppositely disposed marginal sections of the mounting profile rail that can be formed as raised, for example.

To be able to contact the part of the bus system integrated in the mounting rail or to connect the switching devices thereto, said switching devices can advantageously have bus connectors, for example in the form of contact springs, by which the bus line can be contacted, in the region of said mounting profiles, in particular at the lower side of the switching devices.

In an advantageous further development of the invention, the switching devices can be addressed in different manners or variably. The switching devices can in particular receive their addresses by a programming, for example on the commissioning of the switchgear cabinet or of the switching device arrangement. The switching devices can accordingly comprise a programmable address module that can advantageously be controlled or programmed via said bus system.

Alternatively or additionally, the switching devices can comprise reception devices for a device tag, the so-called DT, so that the switching devices can be equipped with device tag modules. Such device tag modules can communicate the device tag to the respective switching device in a wired and/or wireless manner, in particular over radio, and/or to a different device of the switchgear cabinet via the bus system.

Due to said connection of the switching devices to a bus system, they per se only have to have contacts for the main circuit. The commands for the control can be transmitted via the bus system to which the respective switching device is connected.

The supply for the respective switching device can also be ensured via the bus system, which can take place both by the bus system integrated in the mounting profile rail and via the wireless bus system. Alternatively or additionally, the switching devices can, however, also have separate connectors, in particular supply connectors having different voltage levels.

However, commands and/or setting values can also in particular be transmitted to the switching devices via said bus system. Alternatively or additionally, safety-related feedback on the respective state of the switching device can, for example, be transmitted via said bus system, either via the bus strand integrated in the mounting profile rail or via the wireless bus. Such safety-related feedback can, for example, be information on whether the switching device is energized or non-energized, triggered or non-triggered, or on which setting values apply. Operating parameters can furthermore also be transmitted via the bus system, for example the number of previous cycles and/or a degree of wear and/or a residual service life and/or voltage and/or current and/or frequency values in individual phases of the main circuit and/or an asymmetry of the phases and/or a phase shift.

Said control commands and/or feedback can be processed by a programmable control that can be accommodated together with the switching devices in the switchgear cabinet, but can optionally also be positioned outside. Said control can likewise be connected to said bus system and can, for example, be a processor controlled and/or programmable logic controller module.

### BRIEF DESCRIPTION OF THE DRAWINGS

The invention will be explained in more detail in the following with reference to a preferred embodiment and to associated drawings. There are shown in the drawings:

FIG. 1: two switching devices that are pushed onto a top hat rail that on the one hand have bus connectors for connecting to a bus integrated in the top hat rail and wireless bus connectors for connecting to a radio bus system; and

FIG. 2: a partially sectioned representation of the connectors of a switching device to the wired bus system that is integrated in the mounting profile rail; and

FIG. 3: a schematic overall view of a switchgear cabinet having a switching device arrangement in accordance with the preceding Figures and a control device that communicates therewith and that is likewise arranged in the switchgear cabinet.

### DETAILED DESCRIPTION

As FIG. 3 shows, a switchgear cabinet 1 can comprise a main circuit 15 that can comprise power electronic components 16 such as frequency converters, power controllers, rectifiers, and the like. Said main circuit 15 can supply a drive of a large technical system such as a crane, a transfer crane, or a harbor crane, or another hoisting gear, or can also be connected to another large technical system such as a wind turbine.

As FIG. 3 further shows, a switching device arrangement 2 is furthermore accommodated in the switchgear cabinet 1 and comprises a plurality of switching devices 3 that are mounted on one or more mounting profile rails 4 in the form of a top hat rail. Said switching devices 3 can in particular be provided to switch and/or protect the circuits of the main circuit 15 so that said switching devices 3 can each comprise an actuator system for switching the connected circuit or protection elements or other functional modules that are required for the control of the circuit. In addition, said switching devices 3 can have control modules for controlling said actuator system and/or for collecting data from sensor elements, wherein said control modules can, for example, be hardwired logic modules or can also comprise process controlled and/or programmable logic controlled functional modules.

Alternatively or additionally, further switching devices 3 can also be provided on one of said mounting profile rails 4 that form the logic of the control circuit and comprise corresponding functional modules.

As FIG. 3 further shows, a control device 17 can furthermore be accommodated in the switchgear cabinet 1 and transmits control commands to said switching devices 3 and receives the initially named collected data and/or signals from the switching devices.

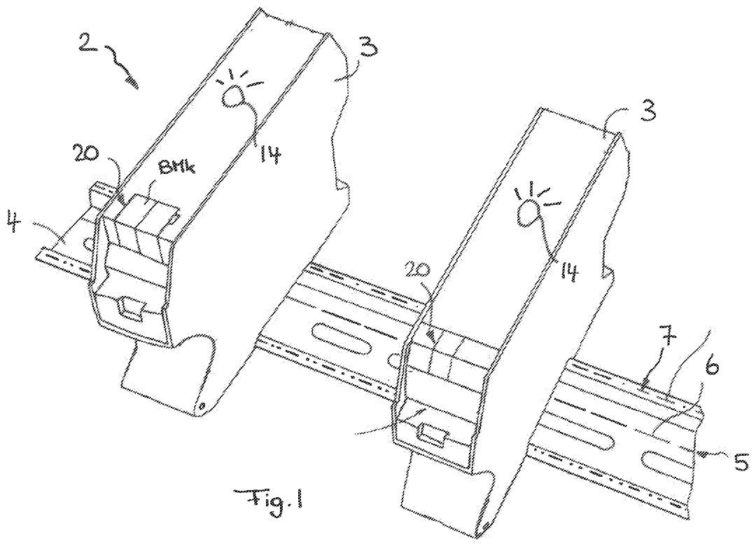

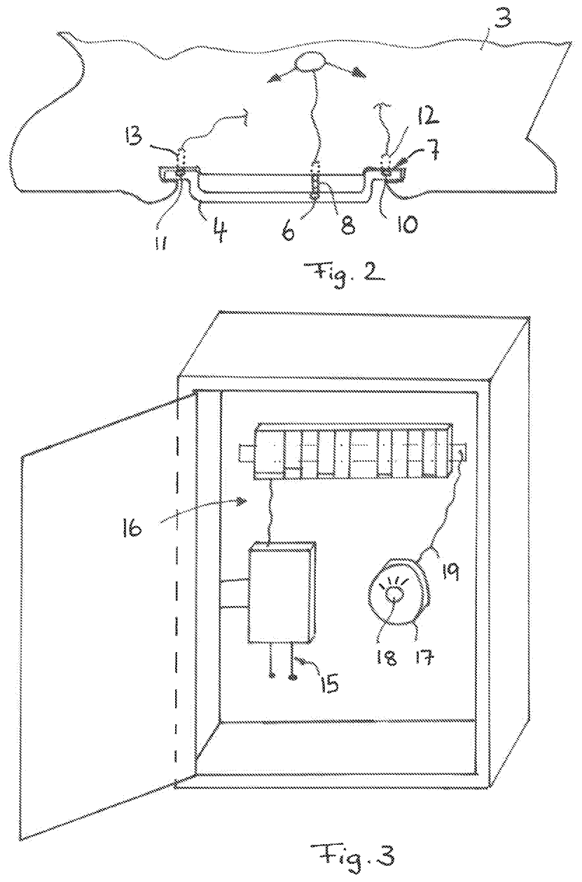

As FIGS. 1 and 2 show, the switching devices 3 pushed or latched onto the mounting profile rail 4 are connected for this purpose to a bus system 5 via which the switching devices 3 receive control commands from the control device 17 and conversely transmit operating parameters such as the number of cycles, voltage and/or current and/or frequency values, degree of wear, and/or residual service life to the control device 17.

As FIGS. 1 and 2 show, said bus system 5 can comprise a databus 6 that can be integrated in the mounting profile rail 4. The corresponding bus line can, for example, be embedded in a middle section 4m of the mounting profile rail 4, for example. To be able to contact said databus line, a respective switching device 3 can comprise a bus connector 8, for example in the form of a contact spring or bush collector, at its lower side that is suitably arranged with respect to the mounting profile 9 that the wired bus connector 8 comes to lie on the databus 6 in the position on the mounting profile rail 4 held by shape matching.

Alternatively or additionally to such a databus 6 embedded in the mounting profile rail 4, a connection between the switching devices 3 and the control device 17 can, however, also comprise a wireless databus 6, in particular in the form of a radio bus. For this purpose, the switching devices 3 can comprise wirelessly operating bus connectors 14 that can in particular be configured as radio transmission and/or reception modules, cf. FIG. 1. Said control device 17 can likewise comprise a wirelessly operating bus connector 18 that can have a corresponding radio transmission and/or reception device to be able to communicate with the switching devices 3 via a radio link.

The control device 17 can furthermore also have a wired bus connector 19 that is connected to the databus 6 that is provided in the mounting profile rail 4.

As FIGS. 1 and 2 further show, an energy bus 7 can also be integrated in the mounting profile rail 4. A voltage supply line 10 and a ground potential line 11 can in particular be embedded or integrated in further sections of the mounting profile rail 4 or can be attached thereto, wherein said voltage supply lines and ground potential lines 10 and 11 are integrated in sections of the profile rail 4 electrically insulated from one another, for example in oppositely disposed marginal sections 41 and 4r or fold webs of the rail 4, cf. FIG. 1. Said sections for the voltage supply lines and the ground potential lines 10 and 11 of the profile rail 4 are advantageously also electrically insulated from the section 4m of the mounting profile rail 4 in which the previously named databus 6 is integrated. Said databus 6 can, for example, be integrated in a base section or middle section of the profile rail 4 to be separated from the two supply lines and ground lines provided at the marginal side.

As FIG. 2 shows, the respective switching device 3 comprises in the region of its mounting profile 9, that can be placed onto the mounting profile rail 4 with shape matching, voltage connectors and ground connectors 12 and 13 at suitable points that can, for example, be configured as contact pins or contact springs to be able to contact the supply lines and ground lines 12 and 13 provided at the profile rail 4, cf. FIG. 2.

As initially explained, the respective switching devices 3 can receive their addresses, for example, by programming on commissioning, with the programming being able to take place via said databus connection. Alternatively or additionally, at least one of the switching devices 3 can also comprise a reception device 20 in which a device tag DT or a device tag module can be received. By equipping the switching devices 3 with such device tags DT, the device tag can be communicated to the switching device in a wired manner or over radio, with a display of the device tag also being able to be provided.

We claim:

1. A switching device arrangement comprising:
a plurality of switching devices mounted together on a mounting profile rail comprising a top hat rail, wherein the switching devices are connected to a bus system comprising at least one databus and/or energy bus for transmitting control signals and/or for an energy supply, wherein the bus system is at least partially integrated in the mounting profile rail and the switching devices have bus connectors configured to connect to the bus system in the mounting profile rail.

2. The device arrangement of claim 1, wherein the switching devices each have a mounting profile at least sectionally complementary to and/or compatible with the mounting profile rail for shape matched connection, pushing and/or latching onto the mounting profile rail, with the bus connectors of the switching devices for connection to the bus system in the mounting profile rail being in the region of the mounting profile.

3. The device arrangement of claim 1, wherein the mounting profile rail comprises rail sections that are electrically insulated from one another and in which different bus system components are accommodated.

4. The device arrangement of claim 1, wherein at least the energy bus is integrated in the mounting profile rail.

5. The device arrangement of claim 1, wherein a voltage supply line and a ground potential line are accommodated in different rail sections of the mounting profile rail electrically insulated from one another and the switching devices have voltage connectors and ground potential connectors that are spaced apart from one another and that are adapted to the spacing of the voltage supply lines and ground potential lines.

6. The device arrangement of claim 5, wherein the voltage supply lines and ground potential lines are arranged in oppositely disposed marginal sections of the mounting profile rail.

7. The device arrangement of claim 1, wherein the data bus is integrated in the mounting profile rail separate from the energy bus.

8. The device arrangement of claim 1, wherein the databus comprises a wirelessly communicating signal bus and the switching devices have wirelessly operating bus connectors each comprising a transmission and/or reception device.

9. The device arrangement of claim 8, wherein the signal bus is a radio bus and the wireless bus connectors each comprise a radio transmission and/or reception device.

10. The device arrangement of claim 1, wherein the switching devices each have a programmable address module in which an address for the respective switching device is storable via the bus system.

11. The device arrangement of claim 1, wherein the switching devices each have a reception device for a device tag module for transmitting a device tag.

12. The device arrangement of claim 1, wherein at least one of the switching devices has a connector for a main circuit and at least one actuator element for switching the main circuit which actuator element can be controlled and/or parameterized via the databus.

13. A switchgear cabinet in which the switching device arrangement of claim 1 is received.

14. The switchgear cabinet of claim 13, wherein a control device for controlling the switching device arrangement and/or a system connectable to the switchgear cabinet is received in the switchgear cabinet in addition to the switching device arrangement.

15. The switchgear cabinet of claim 14, wherein power electronics for controlling a system connectable to the switchgear cabinet such as a crane or a wind turbine is received in the switchgear cabinet in addition to the switching device arrangement.

16. The switchgear cabinet of claim 13, wherein power electronics for controlling a system connectable to the switchgear cabinet such as a crane or a wind turbine is received in the switchgear cabinet in addition to the switching device arrangement.
